(19) United States
(12) Patent Application Publication
(10) Pub. No.: US 2025/0391659 A1
(43) Pub. Date: Dec. 25, 2025

(54) METHOD FOR PATTERNING MASK LAYER OVER SUBSTRATE

(71) Applicant: Tokyo Electron Limited, Tokyo (JP)

(72) Inventor: Minjoon Park, Albany, NY (US)

(21) Appl. No.: 18/750,784

(22) Filed: Jun. 21, 2024

(51) Int. Cl. H01L 21/033; H01L 21/027; H01L 21/311; H01L 21/3213

(52) U.S. Cl. CPC H01L 21/0337; H01L 21/0274; H01L 21/31127; H01L 21/32139

(57) ABSTRACT

A method includes forming a first mask over a substrate, forming a second mask over the first mask, and patterning the second mask to form a patterned second mask. The patterned second mask includes first, second, third, and fourth openings over a first, second, third, and fourth regions of the substrate, respectively. The method further includes forming an organic layer over the patterned second mask, forming a photoresist over the organic layer and patterned second mask, patterning the photoresist to expose the organic layer and the patterned second mask over the first and second regions, etching the organic layer and the first mask to extend the first and second openings into the first mask, removing the organic layer over the third and fourth regions, and etching the first mask to extend the first, second, third, and fourth openings through the first mask and form a patterned first mask.

### TECHNICAL FIELD

The present disclosure relates generally to methods for processing a substrate and, in particular embodiments, to methods for patterning a mask layer over the substrate.

### BACKGROUND

Generally, a semiconductor device, such as an integrated circuit (IC) is fabricated by sequentially depositing and patterning layers of dielectric, conductive, and semiconductor materials over a semiconductor substrate to form a network of electronic components and interconnect elements (e.g., transistors, resistors, capacitors, metal lines, contacts, and vias) integrated in a monolithic structure. At each successive technology node, the minimum feature sizes are shrunk to reduce cost by roughly doubling the component packing density.

Photolithography is a common patterning method in semiconductor fabrication. A photolithography process may start by exposing a coating of photoresist comprising a radiation-sensitive material to a pattern of actinic radiation to define a relief pattern. For example, in the case of positive photoresist, irradiated portions of the photoresist may be dissolved and removed by a developing step using a developing solvent, forming the relief pattern of the photoresist. The relief pattern then may be transferred to a target layer below the photoresist or an underlying hard mask layer formed over the target layer.

### SUMMARY

In accordance with an embodiment of the present disclosure, a method includes forming a first mask layer over a substrate, forming a second mask layer over the first mask layer, and patterning the second mask layer to form a patterned second mask layer. The patterned second mask layer includes a plurality of first openings over a first region of the substrate, a plurality of second openings over a second region of the substrate, a plurality of third openings over a third region of the substrate, and a plurality of fourth openings over a fourth region of the substrate. The method further includes forming an organic layer over the patterned second mask layer. The organic layer overfills the plurality of first openings, the plurality of second openings, the plurality of third openings, and the plurality of fourth openings. The method further includes forming a photoresist layer over the organic layer and patterned second mask layer, patterning the photoresist layer to expose the organic layer and the patterned second mask layer over the first and second regions of the substrate, etching the organic layer and the first mask layer to extend the plurality of first openings and the plurality of second openings into the first mask layer, removing the organic layer over the third and fourth regions of the substrate, and etching the first mask layer to extend the plurality of first openings, the plurality of second openings, the plurality of third openings, and the plurality of fourth openings through the first mask layer and form a patterned first mask layer. In an embodiment, the method further includes: before forming the first mask layer over the substrate, forming a target layer over the substrate, and after forming the patterned first mask layer, transferring a pattern of the patterned first mask layer to the target layer. In an embodiment, removing the organic layer over the third and fourth regions of the substrate includes performing a thermal treatment on the organic layer, the thermal treatment disintegrating the organic layer. In an embodiment, removing the organic layer over the third and fourth regions of the substrate includes performing an etch process on the organic layer. In an embodiment, the method further includes, before forming the photoresist layer over the organic layer and the patterned second mask layer, planarizing the organic layer. In an embodiment, the first mask layer includes amorphous carbon. In an embodiment, the organic layer includes ash-less carbon or spin-on carbon.

In accordance with another embodiment of the present disclosure, a method includes depositing a first mask layer over a substrate, depositing a second mask layer over the first mask layer, and etching the second mask layer to form a patterned second mask layer. The patterned second mask layer includes a first opening over a first region of the substrate, a second opening over a second region of the substrate, a third opening over a third region of the substrate, and a fourth opening over a fourth region of the substrate. A first width of the first opening is less than a second width of the second opening, the second width of the second opening is less than a third width of the third opening, and the third width of the third opening is less than a fourth width of the fourth opening. The method further includes depositing an organic layer over the patterned second mask layer. A top surface of organic layer over is above a top surface of the patterned second mask layer. The method further includes planarizing the organic layer to expose the top surface of the patterned second mask layer, depositing a photoresist layer over the organic layer and patterned second mask layer, patterning the photoresist layer to expose the organic layer and the patterned second mask layer over the first and second regions of the substrate, performing a first etch process on the organic layer and the first mask layer to extend the first opening and the second opening into the first mask layer, removing the organic layer over the third and fourth regions of the substrate, and performing a second etch process on the first mask layer to extend the first opening, the second opening, the third opening, and the fourth opening through the first mask layer and form a patterned first mask layer. In an embodiment, the method further includes: before forming the first mask layer over the substrate, forming a target layer over the substrate, and after forming the patterned first mask layer, transferring a pattern of the patterned first mask layer to the target layer. In an embodiment, the organic layer includes a thermal decomposition material, and removing the organic layer over the third and fourth regions of the substrate comprises performing a thermal treatment on the organic layer. In an embodiment, removing the organic layer over the third and fourth regions of the substrate includes continuing the first etch process. In an embodiment, the first etch process and the second etch process are performed using same process parameters. In an embodiment, the first etch process and the second etch process are performed using different process parameters. In an embodiment, performing the second etch process includes continuing the first etch process.

In accordance with yet another embodiment of the present disclosure, a method includes receiving a substrate. The substrate includes a first mask layer over a target layer and a second mask layer over the first mask layer. The method further includes etching the second mask layer to form a patterned second mask layer including a plurality of regions with different critical dimensions per region, forming an organic layer in the plurality of regions of the patterned second mask layer, forming a first mask layer pattern in at least in one of the plurality of regions, removing the organic layer, forming another first mask layer pattern in another region of the first mask layer, and transferring the first mask layer pattern and the another first mask layer pattern to the target layer. In an embodiment, forming the first mask layer pattern in the at least in one of the plurality of regions includes depositing a photoresist layer over the organic layer and the patterned second mask layer, removing a portion of the photoresist layer to expose the at least in one of the plurality of regions, and performing a first reactive-ion etch process on the organic layer and the first mask layer to partially transfer a second mask layer pattern in the at least in one of the plurality of regions into the first mask layer. In an embodiment, forming the another first mask layer pattern in the another region of the first mask layer includes performing a second reactive-ion etch process on the first mask layer to fully transfer the second mask layer pattern in the at least in one of the plurality of regions into the first mask layer, and fully transfer another second mask layer pattern in the another region into the first mask layer. In an embodiment, the first reactive-ion etch process and the second reactive-ion etch process are performed using same process parameters. In an embodiment, the first etch reactive-ion process and the second reactive-ion etch process are performed using different process parameters. In an embodiment, the organic layer includes a thermal decomposition material and removing the organic layer includes performing a thermal treatment on the organic layer.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1I illustrate cross-sectional views of different stages of a method for patterning a mask layer over a substrate in accordance with various embodiments;

FIG. 1J illustrates a cross-sectional view of a method for transferring a pattern of the patterned mask layer to a target layer formed over the substrate in accordance with various embodiments; and

FIGS. 2A and 2B illustrate a flow diagram of a method for patterning a mask layer over a substrate in accordance with various embodiments.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

Generally, when a mask layer is patterned using a reactive-ion etch (RIE) process to form openings having different widths, an RIE lag causes openings of different widths and/or shapes to be etched differently. For example, openings having smaller widths are etched slower than opening having greater widths, which may cause issues with opening the mask layer using a single RIE process. The widths may be also referred to as critical dimensions.

The present disclosure describes patterning methods that reduce or overcome issues caused by the RIE lag. In various embodiments, one or more regions of the mask layer may be protected by a photoresist layer to compensate etch rate differences between openings formed in protected and unprotected regions. Some embodiments described herein allow for opening the mask layer using a single etch process. Other embodiments described herein allow for opening the mask layer using two etch processes.

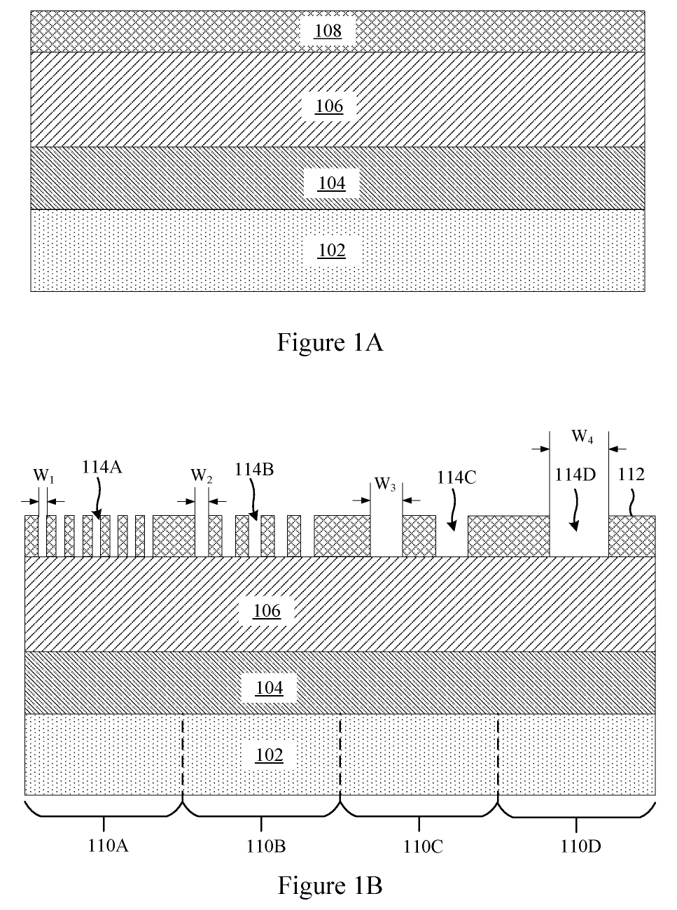

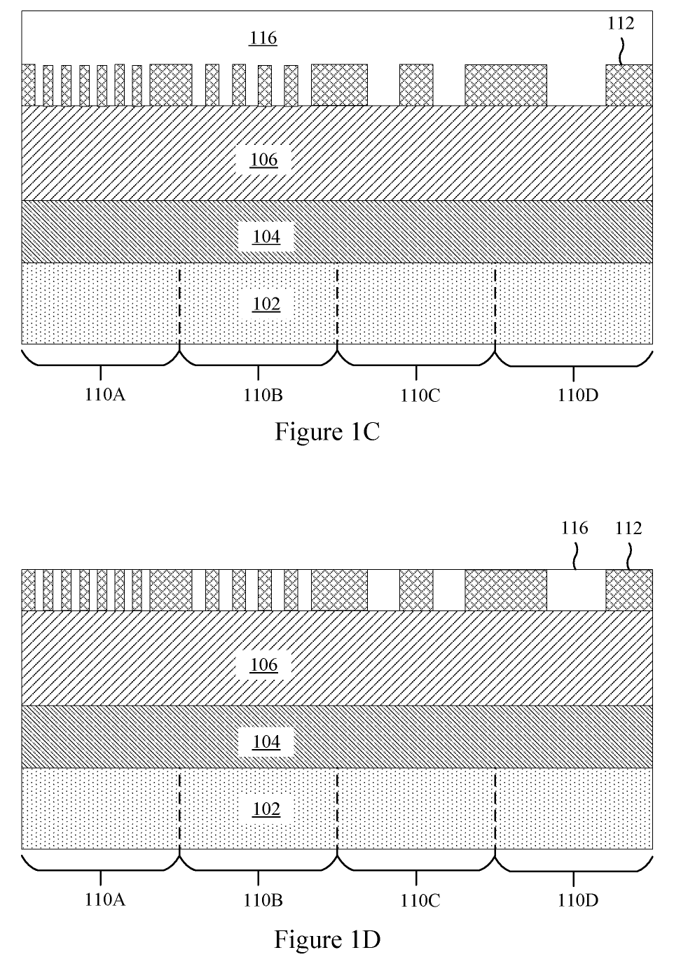

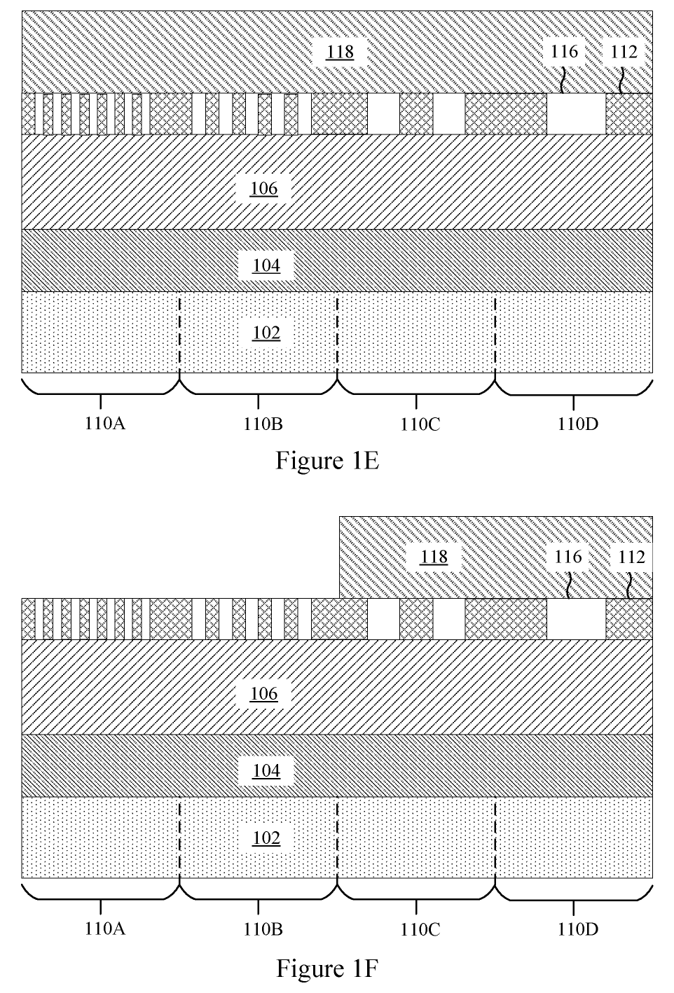

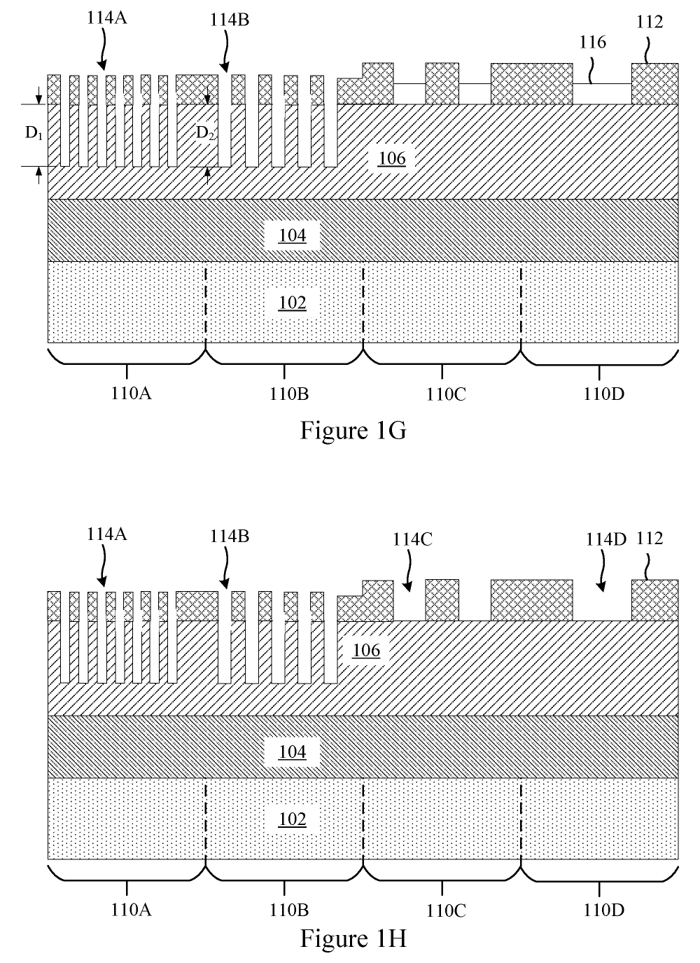

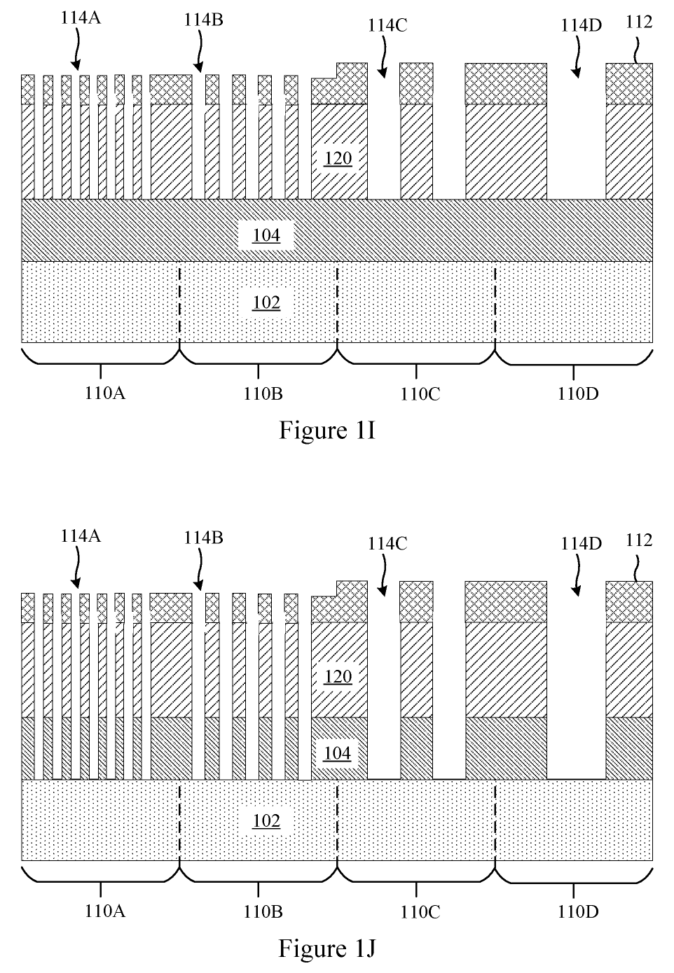

FIGS. 1A-1I illustrate cross-sectional views of different stages of a method for patterning a mask layer 106 over a substrate 102 in accordance with various embodiments. Referring to FIG. 1A, the substrate 102 may be a part of, or include, a semiconductor device or a semiconductor structure, and may be formed in any suitable manner, including using any suitable combination of wet and/or dry deposition, photolithography and etch techniques. For example, the semiconductor structure may comprise the substrate 102 in which various device regions are formed. In such embodiments, the substrate 102 may include isolation regions such as shallow trench isolation (STI) regions, diffusion regions, as well as other regions formed therein. In one embodiment, the semiconductor device is a three-dimensional (3D) NAND device.

The substrate 102 may comprise layers of semiconductors suitable for various microelectronics. In one or more embodiments, the substrate 102 may be a silicon wafer, or a silicon-on-insulator (SOI) wafer. In certain embodiments, the substrate 102 may comprise a silicon germanium wafer, silicon carbide wafer, gallium arsenide wafer, gallium nitride wafer, or other compound semiconductors. In other embodiments, the substrate 102 may comprise heterogeneous layers such as silicon germanium on silicon, gallium nitride on silicon, silicon carbon on silicon, or layers of silicon on a silicon or SOI substrate. In various embodiments, the substrate 102 is patterned or embedded in other components of the semiconductor device or the semiconductor structure.

In some embodiments, a target layer 104 is formed over the substrate 102. The target layer 104 may be a target for pattern transfer in subsequent processing after the formation of the patterned mask layer 120 (see FIG. 1I) is completed. The target layer 104 may comprise silicon, silicon oxynitride, organic material, non-organic material, amorphous carbon, or the like. The target layer 104 may be selected to have anti-reflective properties such as by using a silicon bottom anti-reflective coating (Si-BARC), for example. The target layer 104 may be a mask layer comprising a hard mask. Further, the target layer 104 may be a stacked hard mask comprising, for example, two or more layers of two or more different materials. In embodiments when the hard mask comprises two layers, a first layer of the hard mask may comprise a metal-based layer such as titanium nitride, titanium, tantalum nitride, tantalum, tungsten-based compounds, ruthenium-based compounds, or aluminum-based compounds, and a second layer of the hard mask may comprise a dielectric layer such as silicon dioxide, silicon nitride, silicon oxynitride, silicon carbide, amorphous silicon, or polycrystalline silicon. In some embodiments when a 3D NAND device is formed over the substrate 102, the target layer 104 may comprise alternating oxide (e.g., silicon oxide) and nitride (e.g., silicon nitride) layers. The target layer 104 may be deposited using suitable deposition processes. Suitable deposition processes may include a spin-on coating process, a chemical vapor deposition (CVD) process, an atomic layer deposition (ALD) process, plasma deposition processes (e.g., a plasma-enhanced CVD (PECVD) process, or a plasma-enhanced ALD (PEALD) process), and/or other deposition processes or combinations of processes.

Referring further to FIG. 1A, a mask layer 106 is formed over the target layer 104. In some embodiments, the mask layer 106 may comprise an organic material. The organic material may be a carbon-containing material such as amorphous carbon, boron-doped amorphous carbon, metal-doped amorphous carbon (e.g., W-doped amorphous carbon), Si-doped amorphous carbon, spin-on carbon (SOC), or the like. The organic material may be deposited by a spin-on coating process, a CVD process, an ALD process, plasma deposition processes (e.g., a PECVD process, or a PEALD process), and/or other deposition processes or combinations of processes. In some embodiments, the mask layer 106 has a thickness in a range from 1 µm to 10 µm.

A mask layer 108 is formed over the mask layer 106. In some embodiments, the mask layer 108 may comprise an inorganic material. The inorganic material may comprise silicon oxide, silicon nitride, silicon oxynitride, or the like. The inorganic material may be deposited by a CVD process, an ALD process, plasma deposition processes (e.g., a PECVD process, or a PEALD process), and/or other deposition processes or combinations of processes. In the illustrated embodiment, the mask layer 108 comprises silicon oxynitride. In some embodiments, the mask layer 106 has a thickness in a range from 100 nm to 1 µm.

Referring to FIG. 1B, the mask layer 108 (see FIG. 1A) is patterned to form a patterned mask layer 112. The patterning process may comprise suitable photolithography and etch processes. The suitable etch processes may comprise a wet etch process, a dry etch process, a combination thereof, or the like. The dry etch process may comprise an RIE etch process. In some embodiments, the patterned second mask layer comprises a plurality of regions with patterns having different critical dimensions per region. In the illustrated embodiment, the patterning process forms a plurality of openings 114A in a first region of the patterned mask layer 112 over a region 110A of the substrate 102, a plurality of openings 114B in a second region of the patterned mask layer 112 over a region 110B of the substrate 102, a plurality of openings 114C in a third region of the patterned mask layer 112 over a region 110C of the substrate 102, and a plurality of openings 114D in a fourth region of the patterned mask layer 112 over a region 110D of the substrate 102. In some embodiments, a width W₁ of the openings 114A is in a range from 50 nm to 100 nm, a width W₂ of the openings 114B is in a range from 100 nm to 150 nm, a width W₃ of the openings 114C is in a range from 150 nm to 200 nm, a width W₄ of the openings 114D is greater than 200 nm. In the illustrated embodiment, the width W₁ is less than the width W₂, the width W₂ is less than the width W₃, and the width W₃ is less than the width W₄. The widths may be also referred to as critical dimensions.

Referring to FIG. 1C, an organic layer 116 is formed. In some embodiments, the organic layer 116 may comprise a thermal decomposition material. The thermal decomposition materials are preferably materials that can be removed with a thermal treatment having a temperature range from 100 ℃ to 450 ℃. The thermal decomposition material may comprise ash-less carbon (ALC) material, urethane, polymethyl methacrylate (PMMA), or the like. In some embodiments, the ALC material can be removed by thermal treatment using a temperature from 200 ℃ to 300 ℃. In some embodiments, the ALC material may be deposited by a CVD.

In other embodiments, the organic layer 116 may comprise a material that cannot be removed by a thermal treatment having a temperature range from 100 ℃ to 450 ℃. For example, the organic layer 116 may comprise a spin-on carbon (SOC) material, or the like. In some embodiments, the SOC material may be deposited by a spin-on process. A layer comprising the SOC material may be also referred to an organic planarization layer (OPL).

In some embodiments, the organic layer 116 may be formed to a thickness such that the organic layer 116 overfills the openings 114A, 114B, 114C, and 114D. In such embodiments, the thickness of the organic layer 116 is greater than the thickness of the patterned mask layer 112. In some embodiments, the organic layer 116 has the thickness in a range from 200 nm to 2 µm.

Referring to FIG. 1D, the organic layer 116 is planarized until the patterned mask layer 112 is exposed. In some embodiments, the planarization process may comprise an etch process. The etch process may be a dry etch process such as an O₂ plasma process, for example. After performing the planarization process, a top surface of the organic layer 116 is substantially level or coplanar with a top surface of the patterned mask layer 112 within process variations of the planarization process.

Referring to FIG. 1E, a photoresist layer 118 is formed over the patterned mask layer 112 and the organic layer 116. The photoresist layer 118 may comprise a positive-tone photoresist or a negative-tone photoresist. The photoresist layer 118 may be deposited on the substrate 102 in any suitable manner. For example, the photoresist layer 118 may be deposited by spin-coating, spray-coating, dip-coating, or roll-coating. In other embodiments, the photoresist layer 118 may be deposited using a CVD process, a PECVD process, an ALD process, or other suitable processes. In some embodiments, the photoresist layer 118 has a thickness in a range from 100 nm to 5 µm. In various embodiments, the photoresist layer 118 may comprise an agent-generating ingredient that, in response to a suitable agent-activation trigger (e.g., heat or radiation), generates a solubility-changing agent (e.g., an acid). Example agent-generating ingredients may include a thermal-acid generator (TAG) that is configured to generate an acid in response to heat or a photo-acid generator (PAG) that is configured to generate an acid in response to actinic radiation.

Referring to FIG. 1F, after forming the photoresist layer 118, a reticle (not shown) is disposed over the photoresist layer 118. The reticle may be used to modulate a dose (or an intensity) of a radiation (e.g., actinic radiation) that is used to expose the photoresist layer 118. In such embodiments, the reticle may comprise regions of different transparency to the radiation (e.g., opaque and transparent regions). The photoresist layer 118 is then subject to an exposure step through the reticle. The radiation exposes exposed regions of the photoresist layer 118 while unexposed (or unmodified) regions of the photoresist layer 118 are protected by the reticle. The exposure step may be performed using a photolithographic technique such as dry lithography (e.g., using 193 dry lithography), immersion lithography (e.g., using 193 nanometer immersion lithography), i-line lithography (e.g., using 365 nanometer wavelength UV radiation for exposure), H-line lithography (e.g., using 405 nanometer wavelength UV radiation for exposure), KrF lithography, ArF lithography, ArF-i lithography, extreme UV (EUV) lithography, deep UV (DUV) lithography, or any suitable photolithography technology. In the illustrated embodiment, the exposure step is performed using KrF or i-line lithography.

In some embodiments, the radiation generates an acid in the exposed regions of the photoresist layer 118. The acid may be generated from the PAG that is present in the photoresist layer 118 under the influence of the radiation. The acid may react with the material of the photoresist layer 118 and alter the solubility of the exposed regions of the photoresist layer 118. Subsequently, the exposed regions of the photoresist layer 118 are removed by performing a developing process using a suitable developer. In the illustrated embodiment, the developing process exposes the patterned mask layer 112 and the organic layer 116 over the regions 110A and 110B of the substrate 102, such that the unexposed region of the photoresist layer 118 protects the patterned mask layer 112 and the organic layer 116 over the regions 110C and 110D of the substrate 102.

As described below in greater detail, the openings 114A, 114B, 114C, and 114D are extended into the mask layer 106. In the illustrated embodiments, etch rates for the openings 114A and 114B are less than etch rates for openings 114C and 114D due to RIE lag. The photoresist layer 118 is configured to compensate etch rate differences between the openings 114A and 114B formed over the regions 110A and 110B of the substrate 102 and the openings 114C and 114D formed over the regions 110C and 110D of the substrate 102. In the illustrated embodiments, the photoresist layer 118 protects the mask layer over the regions 110C and 110D of the substrate 102. In other embodiments, the photoresist layer 118 may protect one or more regions of the substrate 102 based on desired compensation of etch rates.

Referring to FIG. 1G, the mask layer 106 is patterned to partially transfer the patterns in the first and second regions of patterned mask layer 112 into the mask layer 106. The patterning process extends the openings 114A and 114B into the mask layer 106, such that bottoms of the openings 114A and 114B are within the mask layer 106. In some embodiments, the patterning process comprises a first etch process while using the patterned mask layer 112 and the photoresist layer 118 (see FIG. 1F) as an etch mask. The first etch process may be a RIE process performed using O₂ plasma. The openings 114A may extend into the mask layer 106 to a depth D₁ and the openings 114B may extend into the mask layer 106 to a depth D₂. In some embodiments, a depth D₁ of the openings 114A is in a range from 500 nm to 9.5 µm, and a depth D₂ of the openings 114B is in a range from 500 nm to 9.5 µm. In some embodiments, the depth D₂ is greater than the depth D₁ due to the etch rate difference.

In some embodiments, the first etch process fully removes the organic layer 116 over the regions 110A and 110B of the substrate 102 and subsequently removes portions of the mask layer 106 over the regions 110A and 110B of the substrate 102 to extend the openings 114A and 114B into the mask layer 106. In some embodiments, the first etch process may further fully remove the photoresist layer 118 (see FIG. 1F) over the regions 110C and 110D of the substrate 102 and partially or fully remove the organic layer 116 over the regions 110C and 110D of the substrate 102. The thickness of the photoresist layer 118 (see FIG. 1F) may be chosen such that, after fully removing the photoresist layer 118, desired depths of the openings 114A and 114B are achieved. In some embodiments, the first etch process may further partially remove the patterned mask layer 112 such that that a greater portion of the patterned mask layer 112 is removed over the regions 110A and 110B of the substrate 102 than over the regions 110C and 110D of the substrate 102. In the illustrate embodiment, the photoresist layer 118 (see FIG. 1F) is fully removed, and a thickness of the patterned mask layer 112 over the regions 110A and 110B of the substrate 102 and a thickens of the organic layer 116 over the regions 110C and 110D of the substrate 102 are less than a thickness of the patterned mask layer 112 over the regions 110C and 110D of the substrate 102.

Referring to FIG. 1H, the organic layer 116 is removed over the regions 110C and 110D of the substrate 102. In some embodiments when the organic layer 116 comprises a thermal decomposition material, the organic layer 116 may be removed by a thermal treatment. In some embodiments, the thermal treatment comprises loading the substrate 102 into a process chamber and baking the substrate 102 at a temperature in a range from 100 ℃ to 450 ℃. The thermal treatment disintegrates the thermal decomposition material into volatile components, which are subsequently removed from the process chamber. In some embodiments when the organic layer 116 comprises the ALC material, the organic layer 116 may be removed by a thermal treatment having a temperature in a range from 300 ℃ to 400 ℃.

In some embodiments when the organic layer 116 comprises the SOC material, the organic layer 116 may be removed by continuing the first etch process described above with reference to FIG. 1G. In such embodiments, the thickness of the photoresist layer 118 (see FIG. 1F) and the thickness of the patterned mask layer 112 (see FIG. 1B) may be chosen such that, after fully removing the photoresist layer 118 and the organic layer 116, desired depths of the openings 114A and 114B are achieved.

Referring to FIG. 1I, the mask layer 106 is patterned to fully transfer the patterns in the first, second, third, and regions regions of patterned mask layer 112 into the mask layer 106. The patterning process extends openings 114A, 114B, 114C, and 114D through the mask layer 106 and forms a patterned mask layer 120. The openings 114A, 114B, 114C, and 114D expose the target layer 104. In some embodiments, the patterning process may partially remove the patterned mask layer 112 such that a thickens of the patterned mask layer 112 is reduced. In some embodiments when the organic layer 116 comprises a thermal decomposition material, the patterning process may be performed by a second etch process while using the patterned mask layer 112 as an etch mask. In some embodiments, the second etch process may be a RIE process performed using O₂ plasma and may have process parameters (e.g., temperature, pressure, and/or O₂ flow rate) same as the first etch process described above with reference to FIG. 1G. In other embodiments, the second etch process may be a RIE process performed using O₂ plasma and may have process parameters (e.g., temperature, pressure, and/or O₂ flow rate) different from the first etch process described above with reference to FIG. 1G.

In some embodiments when the organic layer 116 comprises the SOC material, the patterning process may be performed by continuing the first etch process described above with reference to FIG. 1G while using the patterned mask layer 112 as an etch mask. In other embodiments when the organic layer 116 comprises the SOC material, the patterning process may be performed by a third etch process while using the patterned mask layer 112 as an etch mask. The third etch process may be a RIE process performed using O₂ plasma and may have process parameters (e.g., temperature, pressure, and/or O₂ flow rate) different from the first etch process described above with reference to FIG. 1G.

FIG. 1J illustrates a cross-sectional view of a method for transferring a pattern of the patterned mask layer 120 to the target layer 104 in accordance with various embodiments. In some embodiments, a patterning process is performed to transfer the pattern of the patterned mask layer 120 to the target layer 104. The patterning process may comprise performing an etch process while using the patterned mask layer 120 as an etch mask. The etch process may comprise one or more wet etch processes, one or more dry etch processes, combinations thereof, or the like. The etch process may be anisotropic. The dry etch processes may comprise an RIE process, or the like.

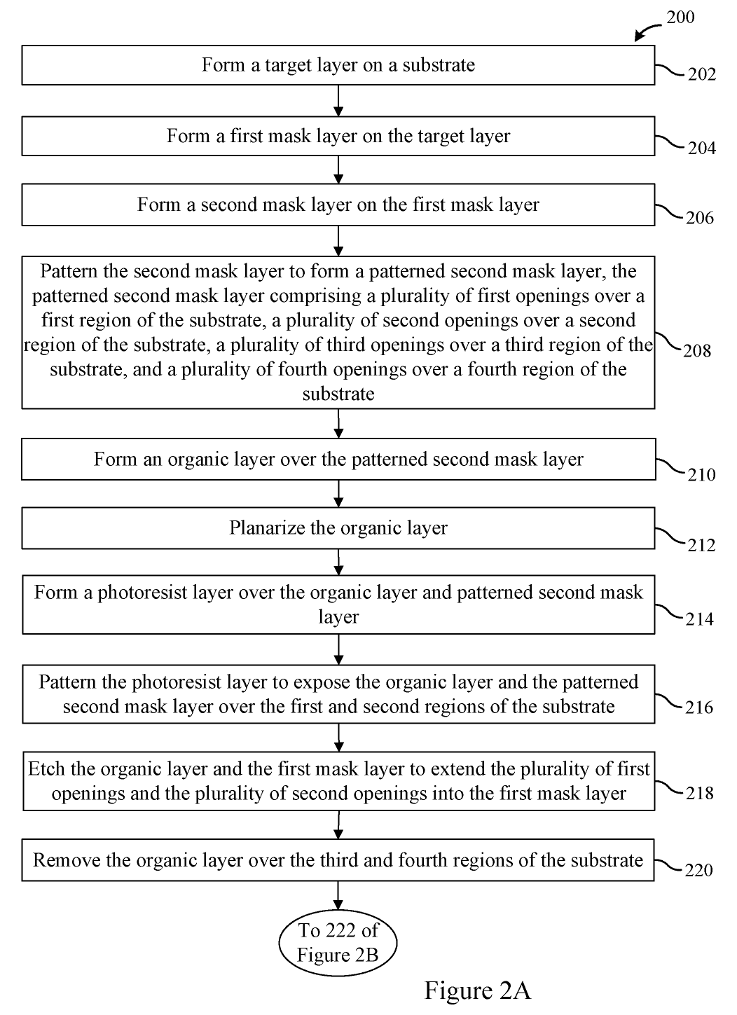

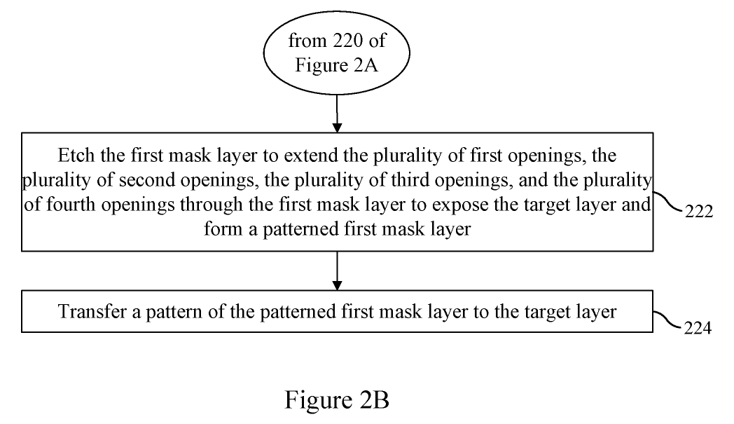

FIG. 2A and 2B illustrate a flow diagram of a method 200 for patterning a mask layer (e.g., mask layer 106 of FIG. 1A) over a substrate (e.g., substrate 102 of FIG. 1A) in accordance with various embodiments. Method 200 starts with step 202. In step 202, a target layer (e.g., target layer 104 of FIG. 1A) is formed on the substrate (e.g., substrate 102 of FIG. 1A) as described above with reference to FIG. 1A. In step 204, a first mask layer (e.g., mask layer 106 of FIG. 1A) is formed on the target layer (e.g., target layer 104 of FIG. 1A) as described above with reference to FIG. 1A. In step 206, a second mask layer (e.g., mask layer 108 of FIG. 1A) is formed on the first mask layer (e.g., mask layer 106 of FIG. 1A) as described above with reference to FIG. 1A.

In step 208, the second mask layer (e.g., mask layer 108 of FIG. 1A) is patterned to form a patterned second mask layer (e.g., patterned mask layer 112 of FIG. 1B) as described above with reference to FIG. 1B. In some embodiments, the patterned second mask layer (e.g., patterned mask layer 112 of FIG. 1B) comprises a plurality of first openings (e.g., openings 114A of FIG. 1B) over a first region (e.g., region 110A of FIG. 1B) of the substrate (e.g., substrate 102 of FIG. 1B), a plurality of second openings (e.g., openings 114B of FIG. 1B) over a second region (e.g., region 110B of FIG. 1B) of the substrate (e.g., substrate 102 of FIG. 1B), a plurality of third openings (e.g., openings 114C of FIG. 1B) over a third region (e.g., region 110C of FIG. 1B) of the substrate (e.g., substrate 102 of FIG. 1B), and a plurality of fourth openings (e.g., openings 114D of FIG. 1B) over a fourth region (e.g., region 110D of FIG. 1B) of the substrate (e.g., substrate 102 of FIG. 1B).

In step 210, an organic layer (e.g., organic layer 116 of FIG. 1C) is formed over the patterned second mask layer (e.g., patterned mask layer 112 of FIG. 1C) as described above with reference to FIG. 1C. In some embodiments, the organic layer (e.g., organic layer 116 of FIG. 1C) overfills the plurality of first openings (e.g., openings 114A of FIG. 1B), the plurality of second openings (e.g., openings 114B of FIG. 1B), the plurality of third openings (e.g., openings 114C of FIG. 1B), and the plurality of fourth openings (e.g., openings 114D of FIG. 1B). In step 212, the organic layer (e.g., organic layer 116 of FIG. 1C) is planarized as described above with reference to FIG. 1D.

In step 214, a photoresist layer (e.g., photoresist layer 118 of FIG. 1E) is formed over the organic layer (e.g., organic layer 116 of FIG. 1E) and patterned second mask layer (e.g., patterned mask layer 112 of FIG. 1E) as described above with reference to FIG. 1E. In step 216, the photoresist layer (e.g., photoresist layer 118 of FIG. 1F) is patterned to expose the organic layer (e.g., organic layer 116 of FIG. 1F) and patterned second mask layer (e.g., patterned mask layer 112 of FIG. 1F) over the first and second regions (e.g., regions 110A and 110B of FIG. 1F) of the substrate (e.g., substrate 102 of FIG. 1F) as described above with reference to FIG. 1F. The remaining portion of the photoresist layer (e.g., photoresist layer 118 of FIG. 1E) protects the third and fourth regions (e.g., regions 110C and 110D of FIG. 1F) of the substrate (e.g., substrate 102 of FIG. 1F).

In step 218, the organic layer (e.g., organic layer 116 of FIG. 1G) and the first mask layer (e.g., mask layer 106 of FIG. 1G) are etched to extend the plurality first openings (e.g., openings 114A of FIG. 1G) and the plurality second openings (e.g., openings 114B of FIG. 1G) into the first mask layer (e.g., mask layer 106 of FIG. 1G) as described above with reference to FIG. 1G. In step 220, the organic layer (e.g., organic layer 116 of FIG. 1G) is removed over the third and fourth regions (e.g., regions 110C and 110D of FIG. 1H) of the substrate (e.g., substrate 102 of FIG. 1H) as described above with reference to FIG. 1H. In some embodiments, the organic layer (e.g., organic layer 116 of FIG. 1G) may be removed by continuing the etch process of step 218. In other embodiments, the organic layer (e.g., organic layer 116 of FIG. 1G) may be removed by a thermal treatment.

In step 222, the first mask layer (e.g., mask layer 106 of FIG. 1H) is etched to extend the plurality first openings (e.g., openings 114A of FIG. 1I), the plurality second openings (e.g., openings 114B of FIG. 1I), the plurality of third openings (e.g., openings 114C of FIG. 1I), and the plurality of fourth openings (e.g., openings 114D of FIG. 1I) through the first mask layer (e.g., mask layer 106 of FIG. 1H) and form a patterned first mask layer (e.g., patterned mask layer 120 of FIG. 1I) as described above with reference to FIG. 1I. In some embodiments, the plurality first openings (e.g., openings 114A of FIG. 1I), the plurality second openings (e.g., openings 114B of FIG. 1I), the plurality of third openings (e.g., openings 114C of FIG. 1I), and the plurality of fourth openings (e.g., openings 114D of FIG. 1I) expose the target layer (e.g., target layer 104 of FIG. 1I).

In some embodiments when the organic layer (e.g., organic layer 116 of FIG. 1G) is removed by continuing the etch process of step 218, the first mask layer (e.g., mask layer 106 of FIG. 1H) is etched by further continuing the etch process of step 218. In other embodiments when the organic layer (e.g., organic layer 116 of FIG. 1G) is removed by a thermal treatment, the first mask layer (e.g., mask layer 106 of FIG. 1H) is etched by a second etch process. In some embodiments, the second etch process may be performed using same process parameters as the etch process of step 218. In other embodiments, the second etch process may be performed using different process parameters form the etch process of step 218. In step 224, a pattern of the patterned first mask layer (e.g., patterned mask layer 120 of FIG. 1J) is transferred to the target layer (e.g., target layer 104 of FIG. 1J) as described above with reference to FIG. 1J.

Example embodiments of the disclosure are described below. Other embodiments can also be understood from the entirety of the specification as well as the claims filed herein.

Example 1. A method including forming a first mask layer over a substrate, forming a second mask layer over the first mask layer, and patterning the second mask layer to form a patterned second mask layer. The patterned second mask layer includes a plurality of first openings over a first region of the substrate, a plurality of second openings over a second region of the substrate, a plurality of third openings over a third region of the substrate, and a plurality of fourth openings over a fourth region of the substrate. The method further includes forming an organic layer over the patterned second mask layer. The organic layer overfills the plurality of first openings, the plurality of second openings, the plurality of third openings, and the plurality of fourth openings. The method further includes forming a photoresist layer over the organic layer and patterned second mask layer, patterning the photoresist layer to expose the organic layer and the patterned second mask layer over the first and second regions of the substrate, etching the organic layer and the first mask layer to extend the plurality of first openings and the plurality of second openings into the first mask layer, removing the organic layer over the third and fourth regions of the substrate, and etching the first mask layer to extend the plurality of first openings, the plurality of second openings, the plurality of third openings, and the plurality of fourth openings through the first mask layer and form a patterned first mask layer.

Example 2. The method of example 1, further including: before forming the first mask layer over the substrate, forming a target layer over the substrate; and after forming the patterned first mask layer, transferring a pattern of the patterned first mask layer to the target layer.

Example 3. The method of one of examples 1 and 2, where removing the organic layer over the third and fourth regions of the substrate includes performing a thermal treatment on the organic layer, the thermal treatment disintegrating the organic layer.

Example 4. The method of one of examples 1 to 3, where removing the organic layer over the third and fourth regions of the substrate includes performing an etch process on the organic layer.

Example 5. The method of one of examples 1 to 4, further including, before forming the photoresist layer over the organic layer and the patterned second mask layer, planarizing the organic layer.

Example 6. The method of one of examples 1 to 5, where the first mask layer includes amorphous carbon.

Example 7. The method of one of examples 1 to 6, where the organic layer includes ash-less carbon or spin-on carbon.

Example 8. A method including depositing a first mask layer over a substrate, depositing a second mask layer over the first mask layer, and etching the second mask layer to form a patterned second mask layer. The patterned second mask layer includes a first opening over a first region of the substrate, a second opening over a second region of the substrate, a third opening over a third region of the substrate, and a fourth opening over a fourth region of the substrate. A first width of the first opening is less than a second width of the second opening, the second width of the second opening is less than a third width of the third opening, and the third width of the third opening is less than a fourth width of the fourth opening. The method further includes depositing an organic layer over the patterned second mask layer. A top surface of organic layer over is above a top surface of the patterned second mask layer. The method further includes planarizing the organic layer to expose the top surface of the patterned second mask layer, depositing a photoresist layer over the organic layer and patterned second mask layer, patterning the photoresist layer to expose the organic layer and the patterned second mask layer over the first and second regions of the substrate, performing a first etch process on the organic layer and the first mask layer to extend the first opening and the second opening into the first mask layer, removing the organic layer over the third and fourth regions of the substrate, and performing a second etch process on the first mask layer to extend the first opening, the second opening, the third opening, and the fourth opening through the first mask layer and form a patterned first mask layer.

Example 9. The method of example 8, further including: before forming the first mask layer over the substrate, forming a target layer over the substrate; and after forming the patterned first mask layer, transferring a pattern of the patterned first mask layer to the target layer.

Example 10. The method of one of examples 8 and 9, where the organic layer includes a thermal decomposition material, and removing the organic layer over the third and fourth regions of the substrate includes performing a thermal treatment on the organic layer.

Example 11. The method of one of examples 8 to 10, where removing the organic layer over the third and fourth regions of the substrate includes continuing the first etch process.

Example 12. The method of one of examples 8 to 11, where the first etch process and the second etch process are performed using same process parameters.

Example 13. The method of one of examples 8 to 12, where the first etch process and the second etch process are performed using different process parameters.

Example 14. The method of one of examples 8 to 13, where performing the second etch process includes continuing the first etch process.

Example 15. A method including receiving a substrate. The substrate includes a first mask layer over a target layer and a second mask layer over the first mask layer. The method further includes etching the second mask layer to form a patterned second mask layer including a plurality of regions with different critical dimensions per region, forming an organic layer in the plurality of regions of the patterned second mask layer, forming a first mask layer pattern in at least in one of the plurality of regions, removing the organic layer, forming another first mask layer pattern in another region of the first mask layer, and transferring the first mask layer pattern and the another first mask layer pattern to the target layer.

Example 16. The method of example 15, where forming the first mask layer pattern in the at least in one of the plurality of regions includes: depositing a photoresist layer over the organic layer and the patterned second mask layer, removing a portion of the photoresist layer to expose the at least in one of the plurality of regions, and performing a first reactive-ion etch process on the organic layer and the first mask layer to partially transfer a second mask layer pattern in the at least in one of the plurality of regions into the first mask layer.

Example 17. The method of example 16, where forming the another first mask layer pattern in the another region of the first mask layer includes performing a second reactive-ion etch process on the first mask layer to: fully transfer the second mask layer pattern in the at least in one of the plurality of regions into the first mask layer, and fully transfer another second mask layer pattern in the another region into the first mask layer.

Example 18. The method of example 17, where the first reactive-ion etch process and the second reactive-ion etch process are performed using same process parameters.

Example 19. The method of one of examples 17 and 18, where the first etch reactive-ion process and the second reactive-ion etch process are performed using different process parameters.

Example 20. The method of one of examples 17 to 19, where: the organic layer includes a thermal decomposition material, and removing the organic layer includes performing a thermal treatment on the organic layer.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the disclosure. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

What is claimed is:

1. A method comprising:
forming a first mask layer over a substrate;
forming a second mask layer over the first mask layer;
patterning the second mask layer to form a patterned second mask layer, wherein the patterned second mask layer comprises a plurality of first openings over a first region of the substrate, a plurality of second openings over a second region of the substrate, a plurality of third openings over a third region of the substrate, and a plurality of fourth openings over a fourth region of the substrate;
forming an organic layer over the patterned second mask layer, wherein the organic layer overfills the plurality of first openings, the plurality of second openings, the plurality of third openings, and the plurality of fourth openings;
forming a photoresist layer over the organic layer and patterned second mask layer;
patterning the photoresist layer to expose the organic layer and the patterned second mask layer over the first and second regions of the substrate;
etching the organic layer and the first mask layer to extend the plurality of first openings and the plurality of second openings into the first mask layer;
removing the organic layer over the third and fourth regions of the substrate; and
etching the first mask layer to extend the plurality of first openings, the plurality of second openings, the plurality of third openings, and the plurality of fourth openings through the first mask layer and form a patterned first mask layer.

2. The method of claim 1, further comprising:
before forming the first mask layer over the substrate, forming a target layer over the substrate; and
after forming the patterned first mask layer, transferring a pattern of the patterned first mask layer to the target layer.

3. The method of claim 1, wherein removing the organic layer over the third and fourth regions of the substrate comprises performing a thermal treatment on the organic layer, the thermal treatment disintegrating the organic layer.

4. The method of claim 1, wherein removing the organic layer over the third and fourth regions of the substrate comprises performing an etch process on the organic layer.

5. The method of claim 1, further comprising:
before forming the photoresist layer over the organic layer and the patterned second mask layer, planarizing the organic layer.

6. The method of claim 1, wherein the first mask layer comprises amorphous carbon.

7. The method of claim 1, wherein the organic layer comprises ash-less carbon or spin-on carbon.

8. A method comprising:
depositing a first mask layer over a substrate;
depositing a second mask layer over the first mask layer;
etching the second mask layer to form a patterned second mask layer, wherein the patterned second mask layer comprises a first opening over a first region of the substrate, a second opening over a second region of the substrate, a third opening over a third region of the substrate, and a fourth opening over a fourth region of the substrate, and wherein a first width of the first opening is less than a second width of the second opening, the second width of the second opening is less than a third width of the third opening, and the third width of the third opening is less than a fourth width of the fourth opening;
depositing an organic layer over the patterned second mask layer, wherein a top surface of organic layer over is above a top surface of the patterned second mask layer;
planarizing the organic layer to expose the top surface of the patterned second mask layer;
depositing a photoresist layer over the organic layer and patterned second mask layer;
patterning the photoresist layer to expose the organic layer and the patterned second mask layer over the first and second regions of the substrate;
performing a first etch process on the organic layer and the first mask layer to extend the first opening and the second opening into the first mask layer;
removing the organic layer over the third and fourth regions of the substrate; and
performing a second etch process on the first mask layer to extend the first opening, the second opening, the third opening, and the fourth opening through the first mask layer and form a patterned first mask layer.

9. The method of claim 8, further comprising:
before forming the first mask layer over the substrate, forming a target layer over the substrate; and
after forming the patterned first mask layer, transferring a pattern of the patterned first mask layer to the target layer.

10. The method of claim 8, wherein:
the organic layer comprises a thermal decomposition material; and
removing the organic layer over the third and fourth regions of the substrate comprises performing a thermal treatment on the organic layer.

11. The method of claim 8, wherein removing the organic layer over the third and fourth regions of the substrate comprises continuing the first etch process.

12. The method of claim 8, wherein the first etch process and the second etch process are performed using same process parameters.

13. The method of claim 8, wherein the first etch process and the second etch process are performed using different process parameters.

14. The method of claim 8, wherein performing the second etch process comprises continuing the first etch process.

15. A method comprising:
receiving a substrate, the substrate comprising:
a first mask layer over a target layer; and
a second mask layer over the first mask layer;
etching the second mask layer to form a patterned second mask layer comprising a plurality of regions with different critical dimensions per region;
forming an organic layer in the plurality of regions of the patterned second mask layer;
forming a first mask layer pattern in at least in one of the plurality of regions;
removing the organic layer;
forming another first mask layer pattern in another region of the first mask layer; and
transferring the first mask layer pattern and the another first mask layer pattern to the target layer.

16. The method of claim 15, wherein forming the first mask layer pattern in the at least in one of the plurality of regions comprises:
depositing a photoresist layer over the organic layer and the patterned second mask layer;
removing a portion of the photoresist layer to expose the at least in one of the plurality of regions; and
performing a first reactive-ion etch process on the organic layer and the first mask layer to partially transfer a second mask layer pattern in the at least in one of the plurality of regions into the first mask layer.

17. The method of claim 16, wherein forming the another first mask layer pattern in the another region of the first mask layer comprises performing a second reactive-ion etch process on the first mask layer to:
fully transfer the second mask layer pattern in the at least in one of the plurality of regions into the first mask layer; and
fully transfer another second mask layer pattern in the another region into the first mask layer.

18. The method of claim 17, wherein the first reactive-ion etch process and the second reactive-ion etch process are performed using same process parameters.

19. The method of claim 17, wherein the first etch reactive-ion process and the second reactive-ion etch process are performed using different process parameters.

20. The method of claim 17, wherein:
the organic layer comprises a thermal decomposition material; and
removing the organic layer comprises performing a thermal treatment on the organic layer.
